(19) United States
(12) Patent Application Publication
(10) Pub. No.: US 2004/0153958 A1
(43) Pub. Date: Aug. 5, 2004

(54) Path metric calculation circuit in viterbi decoders

(76) Inventor: Mario Steinert, Munchen (DE)

Correspondence Address: Andreas Grubert, Baker Botts, L.L.P., 910 Louisiana, One Shell Plaza, Houston, TX, 77002, US

(21) Appl. No.: 10/752,764

(22) Filed: Jan. 7, 2004

(30) Foreign Application Priority Data
Jan. 8, 2003 (DE) DE 103 00 268.5

(51) Int. Cl. H03M 13/03

(52) U.S. Cl. 714/795

(57) ABSTRACT

A Viterbi decoder includes a circuit for calculating transition metric values, that is designed so that one of the calculated transition metric values is set to the value 0 by norming the transition metric values. Further, it has a circuit for updating the path metric values by means of ACS operations, those sections (200) of this circuit, which use the transition metric value normed to the value 0 for ACS operations, have a two's complement arithmetic (21, 23) for performing the comparison operation.

### PRIORITY

This application claims foreign priority of the German application DE 10300268.5 filed on Jan. 8, 2003.

### TECHNICAL FIELD OF THE INVENTION

The invention relates to a circuit and method for recursive calculation of path metric values in a Viterbi decoder.

### DESCRIPTION OF THE RELATED ART

In communication systems (e.g. wireless LAN, mobile radio systems, satellite communication systems), the signal to be emitted is subjected to folding coding (channel coding) for adaptation to the transmission channel. The term Forward Error Correction is used. In folding coding the redundancy is added to the data sequence to be transmitted in order to increase the transmission reliability. The original data sequence is reconstructed in the receiver with the use of the redundancy. A channel decoder is used for this.

Viterbi decoders are used for the channel decoding. Viterbi decoders are based on the processing of the known Viterbi algorithm (VA), by means of which the shortest path is determined recursively by means of a state diagram, which reflects the decoding instruction and is called a trellis diagram. Determining this shortest path by the trellis diagram is equivalent to reconstructing the data sequence, which is supplied to the folding decoder by the transmitter.

The execution of the VA essentially includes three computer routines per interval of time: the calculation of the transition metric values in the trellis diagram, conducting the ACS—(ADD-COMPARE-SELECT) operations for making path decisions for each path and for calculating path metric values and the trace back operation for determining for tracing decision bits back in time with respect to a “surviving” path. For low bit-rate applications the VA can be implemented in software and carried out by a DSP (digital signal processor). However, if a high data throughput and a low latency are required, it is necessary to design the Viterbi decoder completely paralleled in the hardware. In this case the object is to find the most efficient possible implementation of the VA with respect to chip surface, power consumption, and latency.

The module for calculating the path metric values of a Viterbi decoder is considered below. On the one hand this module consists of a unit for calculating transition metric values, BMU (Branch Metric Unit), and on the other hand of a unit for conducting ACS operations, ASCU. The BMU calculates the probabilities of all possible state transitions in the trellis diagram. The ACSU operates recursively and in each recursion step performs an updating of the path metric values for each state in the trellis diagram. For this the ASCU adds the transition metric value to the “old” path metric values, that is, to the path metric values calculated in the preceding time step and in this way determines several candidates for the new path metric value (ADD) for the target state considered. In the subsequent comparison step (COMPARE), the candidate values are compared. In the selection stem (SELECT) the smallest candidate value is selected as a new path metric value for the target state selected.

Next, the mode of operation of a BMU is explained using with example of a code rate R_{c}=½. As is known, the code rate R_{c} designates the ratio of the number of input buts to the number of t output bits of the channel coder and thus is a measure of the redundancy in the coded data stream. Therefore, in the case of a code rate of R_{c}=½ the folding coder generates two output bits per input bit. These two output bits are evaluated in the receiver and are software input values X and Y before the decoding. The pair of values (X, Y) is designated as a detected symbol. The BMU calculates the four possible distances (for R_{c}=½) between the detected symbol (X, Y) and the four hypothetical transmitted symbols (\dot{X}, \dot{Y}). These distances are designated as transition metrics. The equation for calculating the four transition metric values BM₀, BM₁, BM₂, BM₃ is

$$\begin{matrix}\begin{matrix}X - \dot{X} \\ {BM}_{0 , 1 , 2 , 3}\end{matrix} = {( X - \dot{X} )}^{2} + {( Y - \dot{Y} )}^{2} \\ = {X}^{2} + {\dot{X}}^{2} + {Y}^{2} + {\dot{Y}}^{2} - 2 ( X \dot{X} + Y \dot{Y} )\end{matrix} \qquad ( 1 )$$

In so far as the hypothetical symbol values \dot{X} and \dot{Y} in each case may assume the values −1 or 1, the four squared terms in equation (1) are identical for each of the transition metrics. Since in the case of the subsequent processing of the transition metric values BM₀, BM₁, BM₂, BM₃ in ASCU only results in differences between the transition metrics, the squared terms may be ignored. Further, the scaling factor −2 may be replaced by 1. For the hypothetical symbols (\dot{X},\dot{Y})=(1, 1), (1, −1), (−1, 1), (−1, −1) the following transition metric values result:

BM₀=X=Y

BM₁=X−Y

BM₂=Y−X

BM₃=−X−Y (2)

These transition metric values usually are used as input values in the case of the known ACSU. FIG. 1 shows a known implementation of a BMU for R_{c}=½ based on the expressions given in equation (2). The soft input values X and Y concern the inputs 11 and 12 of circuit 10. The adder 13 calculates the transition metric value BM₀, the subtracter 14 forms the transition metric value BM₁. The adder/subtracter 13, 14 must be realized as full adders (FA).

The transition metric values BM₂ and BM₃ are the two's complements of the transition metric values of BM₁, respectively BM₀. Two's complement stages 15, 16 may be used as half-adders (HA) for calculating BM₂ from BM₁, respectively BM₃ from BM₀. The two longest paths of the circuit 10 thus pass through a full adder and a half adder.

A circuit for calculating transition metric values of the given word length in accordance with equation (2) for the code rate R_{c}=½ and analogously defined transition metric values for codes of code rates R_{c}=⅓, ¼, ⅕, ⅙ is described in the document EP 1 223 679 A1.

In “PREST: Power Reduction for System Technology”, by G. Abouyannis et al., Mitel, United Kingdom, Presentation at Portofino, July 2002, pages 8-19, it is stated that in a BMU the transition metric values may be normed so that one of the transition metric values has the value 0.

A fully parallelized ACSU consists of N ACS-components of identical structure, arranged in parallel, N being the number of the states considered in the trellis diagram. Two known implementations for an ACS component of the ACSU are explained by means of FIGS. 2 and 3.

One difficulty in implementing ACS components consists in the fact that the path metric values (that is, the accumulated transition metric values) functions of time increasing without limit. The consequence of this is that the adders, which form the sums of path and transition metric values, run over at some time or other because of the limited word length. This leads to erroneous results in the comparison step. Two different solution set ups for this problem are described in “An Alternative to Metric Rescaling in Viterbi Decoders”, by A. P. Hekstra, IEEE Trans. Commun. Technol., Vol. 37, No. 5, sides 1220-1222, No. 1989.

A first possibility consists in renorming the calculated path metric values in each time step. This set up is used in the ASC component 20.1 shown in FIG. 2. The ASC component 20.1 includes two full adders 21, 22, a comparator COM, a multiplexer MUX, and a subtracter 23. The transition metric value BM₃ and an “old” (that is, determined for the preceding time step) path metric OPMᵢ are added to the full adder 21. The full adder 22 receives the complementary transition metric value BM₃ and another old path metric value OPMⱼ. The indices i and j of the path metric values go from 0 to N−1, in which case i≠j. The indices i and j (that is, the path metric values required by the ACS components 20.1) are defined by the folding code.

The outputs of the two full adders 21 and 22 are supplied to the two inputs of the comparator COM and the two inputs of the multiplexer MUX. The comparator COM determines which of the two sums of every path metric value and transition metric value is smaller, and reports the result to the multiplexer MUX at is control input. The multiplexer MUX thereupon selects the smaller sum of transition metric value and every path metric value. This new path metric value is designated as PM_{n′} and represents the result of an ACS operation without renorming. The index n, n=0, 1, . . . , N−1, indicates the target state, with which the ACS component 20.1 is associated.

The minimum path metric value determined with respect to all values for n in order to avoid a steady increase in the path metric values PM_{n′}: Pm_{min′}=min {PM_{n′}; n=0. 1, . . . , N−1}. The minimum path metric value PM_{min′} is subtracted from PM_{n′} and prevents the renormed “new” path metric value nPMₙ calculated in this way from increasing without limit over the course of time. Further, the decision bit ACS_decₙ determined by the comparison result is output.

One disadvantage of this procedure (renorming path metric values) consists in the fact that the renorming requires a relatively high calculation expense. With respect to this, reference is made to “Viterbi Decoders: High Performance Algorithms and Architectures”, by H. David, O. J. Joeressen, H. Meyr, Digital Signal Processing for Multimedia Systems, Marcel Dekker, Inc., pages 417-459, in particular Chapter 16.4.1.1.

The second possibility for avoiding erroneous decisions in the selection step consists in using a two's compliment modulo arithmetic for performing the comparison operation. In the case of this procedure described in the already mentioned article by A. P. Hekstra and explained by means of FIG. 3, an overrunning of the adders 21, 22 must not be prevented, since in the case of using the two's complement modulo arithmetic with the assumption of a sufficient word length, overrunning of adders 21, 22 does not negatively effect the correctness of the result of comparison.

FIG. 3 shows an ACS component 20.2 built according to this alternative principle. The same or comparable circuit parts as in FIG. 2 are indicated with the same reference numbers. A register reg serves for storing the new path metric value issued by the multiplexer MUX. Instead of the comparator COM, there is a subtracter 24, which performs a subtraction of the two adder outputs in a two's complement representation. As is known, a full adder may be used for the subtraction of numbers in a two's complement representation. At the output of the subtracter 24 the highest valued bit MSB of the subtraction result is output in two's complement representation. This has the value 1 for a negative difference. The modulo operation is produced automatically by the overrunning mechanism of the two's complement arithmetic. The required word length for the path metric values is determined by the following equation:

2^{c-1}≧L·B (3)

In this case c designates the minimally possible word length including the sign bits, L designates the retrogression depth of the folding code, and B designates an upper limit for all possible differences between transition metric values (in the present case B≧|Bmₐ−BM_{b}|, a, b ε {0, 1, 2, 3}). For this two's complement modulo statement without renorming it is absolutely necessary to carry out the comparison step by means of the MSB before the subtraction. The use of a comparator is not necessary, since the latter would not correctly detect the overrunning.

### SUMMARY OF THE INVENTION

The object of the invention is to specify a circuit for recursive calculation of path metric values in a Viterbi decoder, which has a smaller chip surface and a lower power requirement than known circuits. In particular, a low latency also should be attainable. Moreover, the goal of the invention is to specify a method for the recursive calculation of path metric values which has the above-mentioned implementation values.

The basic object of the invention can be achieved by a circuit for recursive calculation of path metric values in a Viterbi decoder, comprising a circuit for calculating transition metric values designed so that one of the calculated transition metric values is set to the value 0 by norming the transition metric values, and a circuit for updating the path metric values by means of ACS operations with the use of the calculated transition metric values, wherein at least those sections of this circuit, which perform ACS operations with the use of the transition metric value normed to the value 0, have a two's complement arithmetic for performing the comparison operation.

The circuit for calculating transition metric values can be designed so that it causes a scaling of the calculated transition metric values by a factor smaller than 1, in particular ½, after the norming. A code to be decoded may have a code rate of ½, and the longest path for calculating transition metric values may have a single full adder. The code to be decoded may have a code rate of ½, and the circuit for calculating transition metric values may calculate normed and scaled transition metric values BM₀=X+Y, BM₁=X, BM₂=Y, and BM₃=0, the pair of values being a received symbol consisting of two soft input values X and Y for one bit coded on the transmitter side. The circuit section processing the transmission metric value set to 0 for updating the path metric values may have a word length c in accordance with the inequality 2^{c-1}≧L·B, c being the minimum whole number for which this inequality is fulfilled, L being the regression depth of the code and B being the smallest upper limit for differences from transition metric values. All sections of the circuit for updating the path metric values performing an ACS operation may have a two's component arithmetic for performing the comparison operation.

The object can furthermore be achieved by a method for the recursive calculation of path metric values in a Viterbi decoder, with the steps:

calculating transition metric values, wherein one of the calculated transition metric values being set to the value 0 by a norming of the transition metric values;

updating the path metric values by means of ACS operations with the use of the calculated transition metric values, the comparison operation being carried out by means of a two's complement arithmetic, at least in the case of those ACS operations, that use the transition metric value normed to the value 0.

A scaling of the calculated transition metric values by a factor smaller than 1, in particular ½, may be performed in the calculation of the transition metric values after the norming.

The object can furthermore be achieved by a method for the recursive calculation of path metric values in a Viterbi decoder, with the steps:

calculating transition metric values,

norming of the transition metric values in such a way that one of the calculated transition metric values is set to the value 0, and

updating the path metric values by means of ACS operations with the use of the calculated transition metric values.

The ACS operation may use a two's complement arithmetic for performing a comparison operation. The step of calculating transition metric values can be designed so that it causes a scaling of the calculated transition metric values by a factor smaller than 1, in particular ½, after the norming. A code to be decoded may have a code rate of ½, and the method may further use a single full adder in the longest path for calculating the transition metric values. The code to be decoded may have a code rate of ½, and the method may further comprise the step of calculating normed and scaled transition metric values BM₀=X+Y, BM₁=X, BM₂=Y, and BM₃=0, wherein the pair of values being a received symbol consisting of two soft input values X and Y for one bit coded on the transmitter side. The method may further comprise the step of using a two's complement arithmetic for updating the path metric values by means of an ACS operation.

In accordance with the present invention, the basic concept of the invention consists in combining two measures advantageously: on the one hand the circuit for calculating transition metric values is designed so that one of the calculated transition metric values is set to the value 0 by norming the transition metric values. In this case at least those sections of the circuit for updating the path metric values by means of ACS operations with the use of the calculated transition metric values, which uses the transition metric value normed to the value 0 for the ACS operation, include a two's complement (modulo) arithmetic for performing the comparison operation.

A significant saving of chip surface and a clear reduction of the power requirements is achieved by means of the combination of these two circuits.

A preferred embodiment of the circuit for calculating transition metric values is designed so that it produces a scaling of the calculated transition metric values by a factor smaller than 1, in particular ½ after the norming. The upper limit B for differences of transition metric values is halved by scaling with the factor ½. In this way the word length of the data paths in the circuit may be reduced for updating the path metric values by means of ACS operations in accordance with equation (3).

An advantageous implementation of the circuit for calculating transition matrix values, that performs the norming of the transition metric values as well as the scaling thereof with the factor ½, is characterized by the fact that the longest path of the circuit has a single full adder. The norming and scaling of the transition metric values require no additional computer expenditure, but, on the contrary, produces a simplification of transition metric values as well as a reduction of their latency.

Further advantageous embodiments of the invention are cited in the subclaims.

### BRIEF DESCRIPTION OF THE DRAWINGS

The invention is explained below by means of an embodiment with reference to the drawing; here:

FIG. 1 shows an ACS unit for calculating transition metric values for a folding code of the code rate R_{c}=½ in accordance with the prior art;

FIG. 2 shows a circuit example of an ACS component for calculating a renormed path metric value in accordance with the prior art;

FIG. 3 shows an alternative circuit example of an ACS component for calculating a path metric value with a two's complement arithmetic in accordance with the prior art;

FIG. 4 shows a schematic circuit diagram of a Viterbi decoder;

FIG. 5 shows a section of a trellis diagram for two time steps where L=7;

FIG. 6 shows a circuit example for a BMU in accordance with the invention for a code rate R_{c}=½; and

FIG. 7 shows a circuit example for an ACS component in accordance with the invention for calculating a path metric value on the basis of transition metric values, that were generated in the circuit shown in FIG. 6.

### DETAILED DESCRIPTION OF THE PREFERRED EMBODIMENTS

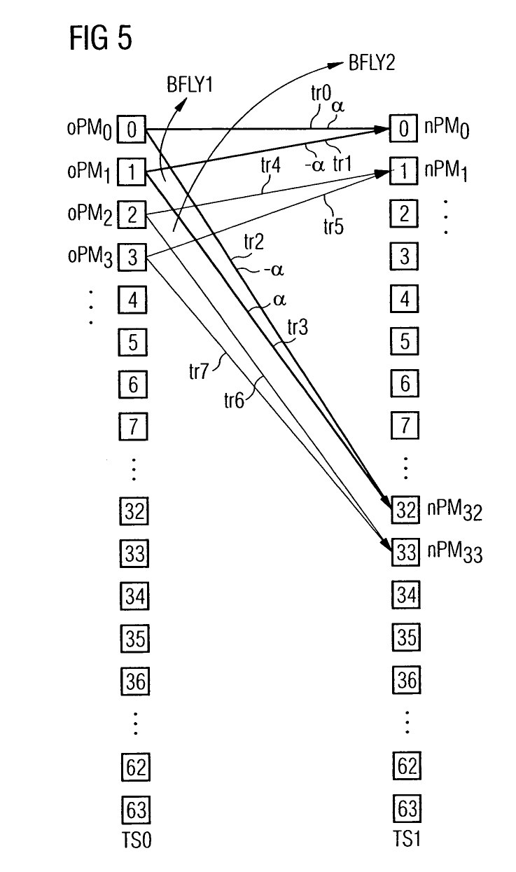

First, the basic construction and general mode of operation of a Viterbi decoder is explained in greater detail below for better understanding of the invention. In accordance with FIG. 4 a Viterbi decoder consists of a unit for calculating transition metric values of a BMU, a unit for carrying out ACS operations, and ACSU, and a unit for storing the survivor management paths determined.

Next, we first start with folding coding with the recursion depth L (corresponds to a shift register with L−1 storage cells) and a code rate R_{c}=½ on the part of the sender. The state of the coder may be expressed at any time step by the occupation of its shift register, that is, there exist 2^{L-1} coding states. The concept of time step refers to the bit sequence of the original, not yet coded data bit stream.

The unit for calculating transition matrix values of a BMU accepts a data stream, which consists of soft input values, that are generated by a detector (e.g. equalizer) upstream (not shown) via data connection 1. There are two soft input values X, Y per time step (where R_{c}=½), each soft input value giving the probability for the appearance of a 1 or a 0 of a detected data bit in the coded signal received.

The BMU for calculating the transition matrix values now calculates a transition metric, which is a measure of the probability of this state transition, taking account of the soft input values X, Y, for each transition in the trellis diagram. The transition metric values calculated by the BMU are supplied to the ACSU via a data connection 2. Reference is made to the section of a trellis diagram with respect to two time steps TS0 and TS1, shown in FIG. 5, in order to explain the computing procedure of the ACSU. FIG. 5 shows a trellis diagram made up of 64 states, as occurs in the case of L=7. In each time step the coder thus may assume one of 64 possible coding states. The 64 possible states of the coders on the sending side are shown in FIG. 5 in the form of sequentially numbered boxes via the time steps TS0 and TS1. The numbers of the states run from 0 to 63.

The ACS operations with respect to the time step TS0 have already been carried out. Then, a path metric value already has been calculated for each of the 64 states in the time step TS0. Further, the path leading to each of these states (sequence of predecessor states) is fixed. The “old” path metric value calculated for the state i, i=0, . . . , 63 calculated in time step TS0, is designated as oPMᵢ below.

The object of the ACS operation consists in calculating a “new” path metric value for each target state in the time step TS1. The new path metric value calculated for the states in the time step TS1 are designated as nPMᵢ, i=0, . . . , 63 below.

The calculation of the new path metric values for the time step TS1 is carried out as follows:

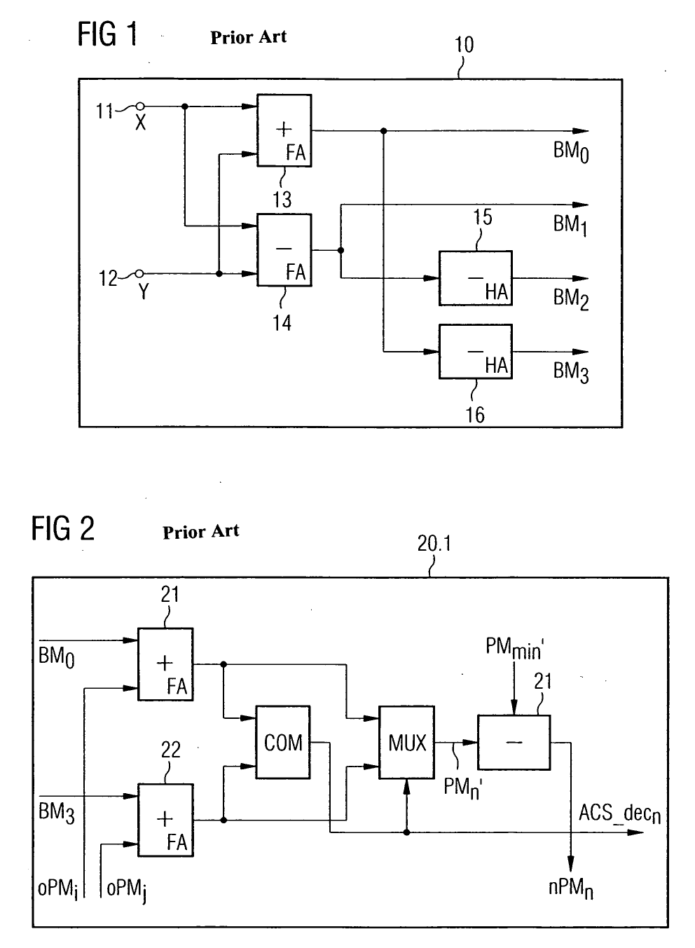

First, the target state 0 is considered. Depending on the value of the input bit in the coding on the transmitter side (which is unknown), the state 0 in the time step TS1is reached either by the state 0 or by the state 1 at the time step TS0. The sums oPM₀+α and oPM₁−α (ADD operation) are formed in order to decide on the more probable of these two predecessor states and thus the more probable of the two possible transitions. In this case α designates the transition metric value belonging to the transition tr0 from the predecessor state 0 to the target state 0, and −α designates the transition metric value belonging to the transition tr1 from the predecessor state 1 to the target state 0. These two transition metric values differ only in the sign in the case of calculating the transition metric values in accordance with FIG. 1.

The smaller of the two sum values is determined (COMPARE operation) and becomes the new path metric value nPM₀ of the state 0 in the time step TS1, that is nPM₀=min {oPM₀+α; oPM₀−α}. The associated transition is selected as the more probable transition of the two possible transitions (SELECT operation). The input bit causing this transition is the decision bit determined by the ACS operation for the target state 0. In this way the more probable transition as well as the more probable predecessor state and the associated decision bit are determined for each state in the time step TS1.

Therefore one ACS operation is to be carried out per target state. In the case of a completely parallelized structure, the ACSU includes these 64 ACS components arranged in parallel to one another, which in each case perform one ACS operation for one target state. Each ACS component needs 2 path metric values and 2 transition metric values, which are complementary (α, respectively −α, as input values.

The other two possible transitions tr2 and tr3 lead from the predecessor states 0 and 1 into time step TS1, for example into state 32 of time stem TS1. In this case the transitions tr2 and tr3 have the same transition metric values, namely −α and α, as the transitions tr1, respectively tr0 (so-called butterfly structure of the transitions in the trellis diagram). The ACS components for calculating the new path metric values nPM₃₂ for the state 32 therefore requires the identical input values (2 path metric values and 2 transition metric values) as the ACS components for calculating the path metric value nPM₀. The transitions tr1, tr2, tr3, and tr4 define a first butterfly BPLY1.

FIG. 5 further shows an analogously formed butterfly BFLY2 consisting of the old path metric values oPM₂ and oPM₃ and the associated now path metric values nPM₁ and nPM₃₃ (transitions tr4, tr5, tr6, tr7, represented by thin lines).

For a trellis diagram with 64 states and a folding code with a code rate of R_{c}=½, therefore in accordance with FIG. 2 the ACSU requires a number of 128 inputs of transition metric values (2 items per target state). Since (in the case of a completely parallelized structure) 64 ACS components are present, of which in each case two ACS components receive the same transition metric values, the ACSU as a whole has 32 inputs for transition metric values. As explained in FIG. 5, complementary transition metric values −α and α always are further processed from each ACS component in the prior art (FIG. 1).

The loop 3 in FIG. 4 makes clear that the trellis diagram shown in sections in FIG. 5 is executed time step by time step, all new path metric values nPMᵢ; i=0, . . . , 63, always being calculated and then used in the next time step as old path metric values oPMᵢ, i=0, . . . , 63. After the path metric values were updated over one or more time steps and the associated decision bits (64 per time step) were determined in each case, and the SMU reported via the data connection 4, the SMU carries out a trace back operation. The trace back operation is used for determining the correct bit (namely the input bit of the coder) from the 64 decision bits (one decision bit per path) obtained per time step. This bit then is output via data connection 5.

For this purpose the SMU utilizes the property that the individual paths converge in the temporal backwards direction and agree from a certain temporal trace back length. Therefore a decided bit tracing back by the trace back length is determined with respect to (any) one of the surviving paths in the trace back operation.

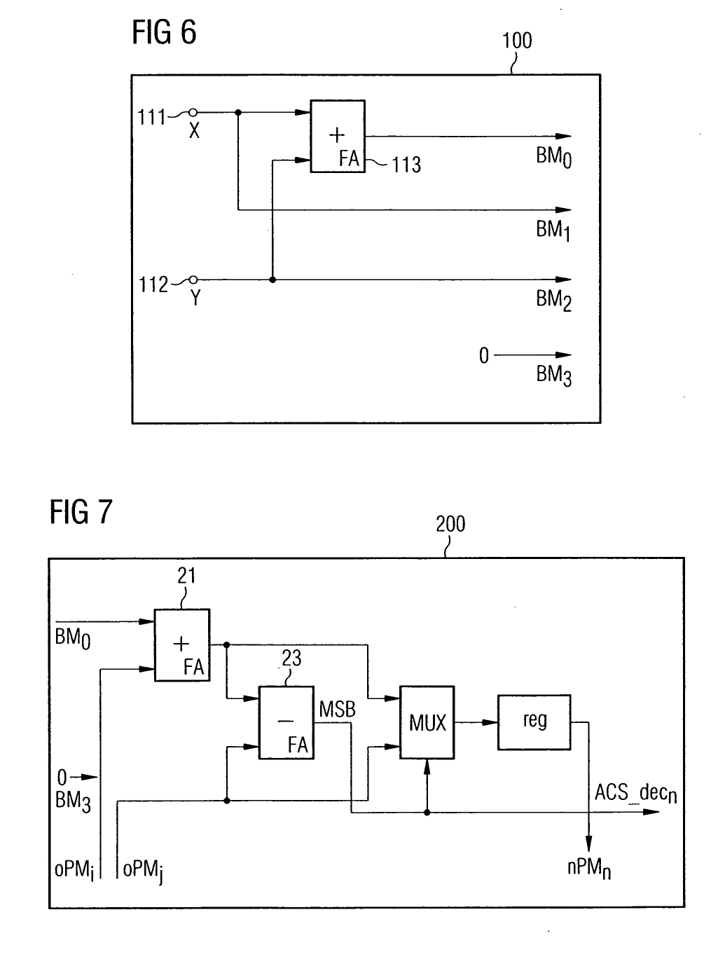

FIG. 6 shows a circuit 100 of a BMU in accordance with the invention for the example R_{c}=½. Circuit 100 has a single full adder 113, the adder inputs of which are connected with the inputs 111 and 112 of circuit 100. The soft input values X and Y, which represent a symbol, are present at inputs 111 and 112.

Circuit 100 generates the following transition metric values:

BM₀=X+Y

BM₁=X

BM₂=Y

BM₃=0 (4)

It is shown below that the transition metric values specified in equation (4) also are suited as input values for the ACS components of the ACSU. The absolute values of the transition metrics have no influence on the decisions that are made in the ACS operations, but only differences between transition metric values. Thus the comparison results determined in the ACS components are not influenced by the addition of a constant value to all transition metric values. The normed transition metric values result from an addition of X+Y to the transition metric values given in equation (2)

BM₀=(X+Y)+(X+Y)=2(X+Y)

BM₁=(X−Y)+(X+Y)=2X

BM₂=(Y−X)+(X+Y)=2Y

BM₃=(−X−Y)+(X+Y)=0 (5)

The transition metric values given in equation (4) follow from the values given in equation (5) by means of a scaling with the factor ½. One of the transition metric values (BM₃) here constantly has the value 0. The complementary property of the transition metric values explained by means of FIG. 5 is no longer given at a target state.

A comparison of FIGS. 1 and 6 makes clear that the norming and scaling significantly simplifies the implementation of the BMU. The longest path (that also is called the “critical” path in the technical literature) through circuit 100 includes only one single full adder 113 of the given transition metric word length.

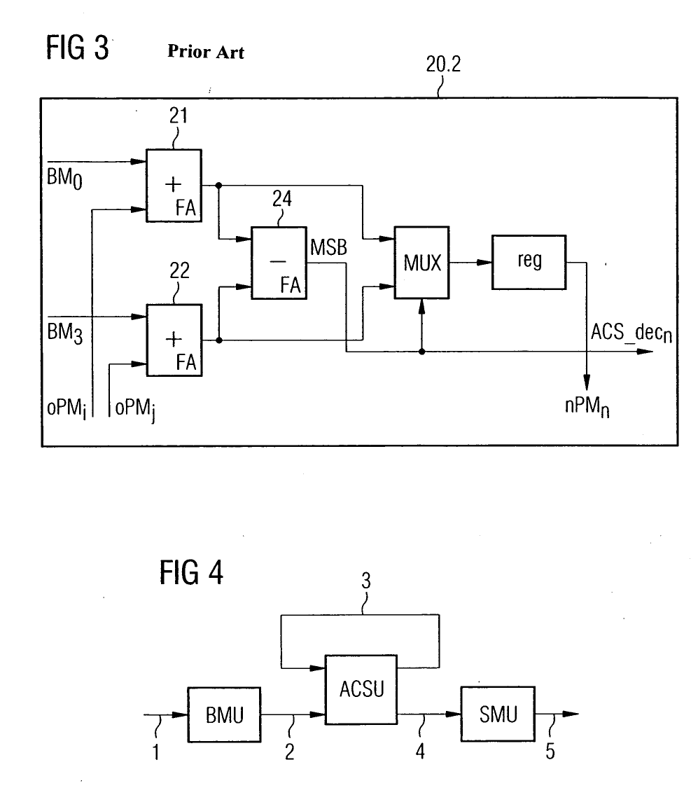

FIG. 7 shows an ACS component 200, which assumes the transition metric value BM₃=0. This ACS component 200 differs from the known ACS component shown in FIG. 3 by the fact that the full adder 22 is absent. The representation of the values in the circuit 200 takes place in the two's component (that is, as a binary number, the highest value bit being a sign bit: in the case of a positive number the sign bit in a two's complement representation has the value 0. In the case of a negative number the sign bit in two's complement representation has the value 1, and the following places in the two's complement representation result from the usual dual number representation by negation of all places and addition of 1.). The subtracter 23 is a full adder (of course, the subtraction of two values is replaced by an addition of the values in the two's complement representation).

The mode of operation of the circuit shown in FIG. 7 is based on the same principle as the mode of operation of the circuit from FIG. 3, that is known from the article by A. P. Hekstra: overrunning of the adder 21 in a two's complement representation causes the value BM₀+oPMᵢ to be replaced by the residual value (BM₀+oPMᵢ)mod2^{c}. As long as the inequality (3) is fulfilled, the result of the comparison step (that is, the value of the highest valued bit MSB) is not influenced by the modulo operation. In this case, in comparison with the known circuit shown in FIG. 3, there is the further advantage that the value B for the transition metric values generated with the scaling 100 (FIG. 6) is only ½ as large as the value B for the transition metric values generated with the known circuit 10. As a result of which in accordance with equation (3) a word length smaller by 1 bit than in circuit 20.2 may be used in circuit 200.

The critical path of the ACS component 100 is not influenced by the modification, that is, it is neither lengthened nor shortened. As in the circuit 20.2 shown in FIG. 3, the critical path runs from the register reg (in which the new, respectively old path metric values are stored) via the adder 21, the subtracter 23, the control input of the multiplexer MUX, and back to the register reg.

It is to be noted that the input of the normed and scaled transition metric values in accordance with equation (4) into the known circuit 20.1 also is fundamentally possible, but offers no advantage there. The reason for this is that the implementation gain achieved with the BMU 100 in accordance with the invention is (over) compensated by means of a higher in the case of resealing in the circuit 20.1, since the transition metric values PM_{n′} now can overrun both in the positive and in the negative direction. That is, although the adder 22 also could be omitted in the circuit 20.1 shown in FIG. 2 (since BM₃=0), a further adder would have to be used for the rescaling in addition to the subtracter 23. The implementation advantage achieved with the invention first is obtained in the case of the combination of the circuit 100 shown in FIG. 6 for generating normed and scaled transition metric values with the ACS component 200 based on the two's complement arithmetic.

The overall circuit 100, 200 for calculating path metric values in accordance with the invention may be combined both with an SMU of the REA (register exchange algorithm) type as well as with an SMU of the TBA (trace back algorithm) type. The values cited in the following table with respect to the need for storage surface and power consumption refer to the path metric unit (BMU, ACSU) and to the total Viterbi decoder (BMU, ACSU, SMU). An REA implementation was chosen for the SMU. The chip surface is given in units of 10³ gates. The power consumption is given in mW. The parameters L=7 (trellis diagram with 4 states) and R_{c}=½ are the basis of the data. The prior art is represented by the BMU 10 in combination with a completely parallelized ACSU consisting of 64 ACS components 20.2. The invention is represented by the BMU 100 in combination with a completely parallelized ACSU consisting of 32 ACS components 200 and 32 ACS components 20.2.

TABLE

| | chip surface (kGates) | | power consumption (mW) | |
|---|---|---|---|---|
| | | BMU, | | BMU, |
| | BMU, | ACSU, | BMU, | ACSU, |
| | ACSU | SMU | ACSU | SMU |
| prior art | 17.33 | 74.25 | 46.47 | 131.7 |
| invention | 12.96 | 69.24 | 26.00 | 106.8 |
| saving | 25% | 6.7% | 44% | 19% |

The table shows that around 25% of the chip surface for calculating the path metric values (BMU, ACSU) is saved. With respect to the entire decoder, the saving in chip surface is only 6.7%. This is because an SMU of the REA type was used, the implementation of which is known to require a high amount of chip surface (as is known in the technology in general, an REA implementation consist of N parallel chains of register/multiplexer units, the length of each chain having to correspond at least to the trace back length). A greater saving of chip surface takes place in the case of a TBA implementation of the SMU (with the disadvantage of a greater latency of the decoder).

Clear savings of 44% for the path metric calculation (BMU, ACSU) and 19% for the entire decoder (BMU, ASCU, SMU) are achieved in the power consumption.

The invention may be applied to code rates of the general form R_{c}=n/k, n being the number of uncoded bits per state transition and k the number of coded bits and thus designating the number of the soft input values per symbol. The number of the transition metric values to be calculated in the BMU is 2^{k}. The idea of the invention is applicable for all code rates with any values of n and k, since it is always possible to norm one of the calculated transition metric values to the value 0. Of course, the effect achieved with the invention decreases with increasing numerator k. For example, eight transition metric values must be processed in the ACSU for R_{c}=n/3, only one of these transition metric values having the value 0. Consequently, an adder in accordance with circuit 200 may be saved only in each fourth (since in each case two transition metric values go to each ACS component).

1. A circuit for recursive calculation of path metric values in a Viterbi decoder, comprising
a circuit for calculating transition metric values designed so that one of the calculated transition metric values is set to the value 0 by norming the transition metric values, and
a circuit for updating the path metric values by means of ACS operations with the use of the calculated transition metric values, wherein at least those sections of this circuit, which perform ACS operations with the use of the transition metric value normed to the value 0, have a two's complement arithmetic for performing the comparison operation.

2. The circuit in accordance with claim 1, wherein
the circuit for calculating transition metric values is designed so that it causes a scaling of the calculated transition metric values by a factor smaller than 1, in particular ½, after the norming.

3. The circuit in accordance with claim 1, wherein a code to be decoded has a code rate of ½, and the longest path for calculating transition metric values has a single full adder.

4. The circuit in accordance with claim 1, wherein the code to be decoded has a code rate of ½, and the circuit for calculating transition metric values calculates normed and scaled transition metric values BM₀=X+Y, BM₁=X, BM₂=Y, and BM₃=0, the pair of values being a received symbol consisting of two soft input values X and Y for one bit coded on the transmitter side.

5. The circuit in accordance with claim 1, wherein the circuit section processing the transmission metric value set to 0 for updating the path metric values has a word length c in accordance with the inequality 2^{c-1}≧L·B, c being the minimum whole number for which this inequality is fulfilled, L being the regression depth of the code and B being the smallest upper limit for differences from transition metric values.

6. The circuit in accordance with claim 1, wherein all sections of the circuit for updating the path metric values performing an ACS operation have a two's component arithmetic for performing the comparison operation.

7. A method for the recursive calculation of path metric values in a Viterbi decoder, with the steps:
calculating transition metric values, wherein one of the calculated transition metric values being set to the value 0 by a norming of the transition metric values;
updating the path metric values by means of ACS operations with the use of the calculated transition metric values, the comparison operation being carried out by means of a two's complement arithmetic, at least in the case of those ACS operations, that use the transition metric value normed to the value 0.

8. The method in accordance with claim 7, wherein a scaling of the calculated transition metric values by a factor smaller than 1, in particular ½, is performed in the calculation of the transition metric values after the norming.

9. A method for the recursive calculation of path metric values in a Viterbi decoder, with the steps:
calculating transition metric values,
norming of the transition metric values in such a way that one of the calculated transition metric values is set to the value 0, and
updating the path metric values by means of ACS operations with the use of the calculated transition metric values.

10. The method in accordance with claim 9, wherein the ACS operation uses a two's complement arithmetic for performing a comparison operation.

11. The method in accordance with claim 9, wherein the step of calculating transition metric values is designed so that it causes a scaling of the calculated transition metric values by a factor smaller than 1, in particular ½, after the norming.

12. The method in accordance with claim 9, wherein a code to be decoded has a code rate of ½, and further using a single full adder in the longest path for calculating the transition metric values.

13. The method in accordance with claim 9, wherein the code to be decoded has a code rate of ½, and further comprising the step of calculating normed and scaled transition metric values BM₀=X+Y, BM₁=X, BM₂=Y, and BM₃=0, wherein the pair of values being a received symbol consisting of two soft input values X and Y for one bit coded on the transmitter side.

14. The method in accordance with claim 9, comprising the step of using a two's complement arithmetic for updating the path metric values by means of an ACS operation.
